(19) United States
(12) Patent Application Publication
(10) Pub. No.: US 2024/0273358 A1
(43) Pub. Date: Aug. 15, 2024

(54) ARTIFICIAL-INTELLIGENCE-BASED PREDICTION OF STORAGE CAPACITIES IN WATER RESERVOIRS

(71) Applicant: Trabus, San Diego, CA (US)

(72) Inventors: David SATHIARAJ, San Diego, CA (US); Eric Vincent ROHLI, San Diego, CA (US); Nicholas WOOLSEY, San Diego, CA (US)

(21) Appl. No.: 18/439,496

(22) Filed: Feb. 12, 2024

Related U.S. Application Data
(60) Provisional application No. 63/484,663, filed on Feb. 13, 2023.

(51) Int. Cl. G06N 3/08; G06F 30/27; G06N 3/0442

(52) U.S. Cl. CPC G06N 3/08; G06F 30/27; G06N 3/0442

(57) ABSTRACT

Predicting the storage capacities of water reservoirs is an important planning activity for effective conservation and water release practices. However, current state-of-the-art solutions are not generalizable to all water reservoirs. Accordingly, disclosed embodiments train a machine-learning model using a training dataset that comprises labeled feature vectors that each includes a time series of tuples and is labeled with the target value of at least one storage parameter for a water reservoir. Each tuple may comprise climate parameter(s), such as temperature, precipitation, and/or soil moisture, for the watershed of the water reservoir, and/or reservoir parameter(s), such as water level, water storage, storage capacity, water inflow, and/or water outflow of the water reservoir. The machine-learning model may be a recurrent neural network with long short-term memory, that is trained to predict the value of the storage parameter at least seven days into the future.

### CROSS-REFERENCE TO RELATED APPLICATIONS

This application claims priority to U.S. Provisional Patent App. No. 63/484,663, filed on Feb. 13, 2023, which is hereby incorporated herein by reference as if set forth in full.

### BACKGROUND

### Field of the Invention

The embodiments described herein are generally directed to artificial intelligence (AI), and, more particularly, to AI-based prediction of storage capacities in water reservoirs.

### Description of the Related Art

Water-resource management plays an important role in the climate resilience of a community. Water reservoirs can be used to supply water resources to nearby communities, generate clean hydroelectric energy, allow aquatic recreation in inland areas, provide habitats for marine life, and/or the like. Water reservoirs can also be used to mitigate against weather-induced changes in local water balance. For example, during dry periods, water reservoirs can provide water to sustain nearby agricultural industries. Conversely, during heavy precipitation events, water reservoirs with excess storage capacity can accept extra runoff, to thereby reduce the impact of flash floods.

Water-resource managers must be able to predict near-term water levels in a water reservoir, to maintain optimal operating conditions and prevent unnecessary risks, such as surface-water scarcity in nearby communities. However, the prediction of water levels is difficult and complex, especially in view of the non-linearities associated with processing data from episodic natural phenomena, time lags between precipitation and changes in water levels due to the flow of water through drainage basins, uncertainties of weather forecasts, and the like. Unsurprisingly, there are not many tools available to water-resource managers. Moreover, the tools that exist are not generalizable to all water reservoirs. The present disclosure is directed toward overcoming these and other problems discovered by the inventors.

### SUMMARY

Systems, methods, and non-transitory computer-readable media are disclosed for AI-based prediction of storage capacities in water reservoirs.

In an embodiment, a method comprises using at least one hardware processor to, during a training phase: acquire a training dataset comprising a plurality of labeled feature vectors, wherein each of the plurality of labeled feature vectors comprises a time series of a plurality of tuples, wherein each of the plurality of tuples comprises a value for each of one or more climate parameters and one or more reservoir parameters for a respective water reservoir, and wherein each of the plurality of labeled feature vectors is labeled with a target value of at least one storage parameter of the respective water reservoir; and use the training dataset to train a machine-learning model to predict a value of the at least one storage parameter for any of a plurality of water reservoirs, wherein the machine-learning model comprises a recurrent neural network with long short-term memory (LSTM).

The recurrent neural network may comprise an LSTM structure and a densely connected structure. The LSTM structure may comprise at least one layer of nodes, wherein the densely connected structure comprises a plurality of layers of nodes. Each layer of nodes in the LSTM structure and the densely connected structure may have an identical number of nodes. The number of nodes may be at least fifty. Each node in the at least one layer of the LSTM structure may be connected to every node in an initial one of the plurality of layers of the densely connected structure. Each node in each of the plurality of layers of the densely connected structure may be connected to every node in each adjacent one of the plurality of layers of the densely connected structure. The recurrent neural network may further comprise an aggregation node that outputs the predicted value of the at least one storage parameter, wherein each node in a final one of the plurality of layers of the densely connected structure is connected to the aggregation node.

The one or more climate parameters may comprise temperature and precipitation. The one or more reservoir parameters may comprise either a water level of the respective water reservoir, water storage in the respective water reservoir, or a storage capacity of the respective water reservoir.

The at least one storage parameter may comprise either a water level of the respective water reservoir, a change in water level of the respective water reservoir, water storage in the respective water reservoir, a change in water storage in the respective water reservoir, a storage capacity of the respective water reservoir, or a change in storage capacity of the respective water reservoir.

Each of the plurality of tuples in each time series may represent one time interval within a plurality of consecutive time intervals. Each of the plurality of consecutive time intervals may be a twenty-four-hour period, wherein the time series comprises at least fourteen tuples. The target value of the at least one storage parameter, with which each of the plurality of feature vectors is labeled, may represent the at least one storage parameter at a subsequent time interval that is at least seven time intervals after a last one of the plurality of consecutive time intervals represented by the plurality of tuples in that feature vector.

Acquiring the training dataset may comprise generating the training dataset, wherein generating the training dataset comprises, for at least one water reservoir: acquiring historical climate data that comprise observed values of the one or more climate parameters, spatially scattered in a non-uniform manner; deriving a gridded dataset by interpolating a value of each of the one or more climate parameters for each of a plurality of points in a uniform grid based on the observed values of the one or more climate parameters in the historical climate data; and calculating the value of each of the one or more climate parameters for the at least one respective water reservoir from the gridded dataset. The value of each of the one or more climate parameters for the at least one water reservoir may be calculated by spatially aggregating a plurality of values of that climate parameter for at least a subset of the plurality of points representing a watershed of the at least one water reservoir.

Each of the plurality of tuples may comprise a value of the at least one storage parameter, and the method may further comprise using the at least one hardware processor to, during the training phase, validate the machine-learning model, wherein validating the machine-learning model comprises, for each of one or more feature vectors in a validation subset of the training dataset, in each of a plurality of iterations: input the feature vector to the machine-learning model to predict the value of the at least one storage parameter; create a new tuple comprising the predicted value of the at least one storage parameter; remove one of the plurality of tuples from a front of the feature vector; and add the new tuple to an end of the feature vector.

The method may further comprise using the at least one hardware processor to, during an operation phase: receive an input feature vector comprising a time series of a plurality of tuples, wherein each of the plurality of tuples in the time series of the input feature vector comprises a value for each of the one or more climate parameters and the one or more reservoir parameters for a water reservoir of interest; apply the trained machine-learning model to the input feature vector to predict the value of the at least one storage parameter for the water reservoir of interest in at least one future time interval; and output the predicted value of the at least one storage parameter for the water reservoir of interest in the at least one future time interval to at least one downstream function.

It should be understood that any of the features in the methods above may be implemented individually or with any subset of the other features in any combination. Thus, to the extent that the appended claims would suggest particular dependencies between features, disclosed embodiments are not limited to these particular dependencies. Rather, any of the features described herein may be combined with any other feature described herein, or implemented without any one or more other features described herein, in any combination of features whatsoever. In addition, any of the methods, described above and elsewhere herein, may be embodied, individually or in any combination, in executable software modules of a processor-based system, such as a server, and/or in executable instructions stored in a non-transitory computer-readable medium.

### BRIEF DESCRIPTION OF THE DRAWINGS

The details of the present invention, both as to its structure and operation, may be gleaned in part by study of the accompanying drawings, in which like reference numerals refer to like parts, and in which:

FIG. 1 illustrates an example infrastructure, in which one or more of the processes described herein may be implemented, according to an embodiment;

FIG. 2 illustrates an example processing system, by which one or more of the processes described herein may be executed, according to an embodiment;

FIG. 3 illustrates a process for training a machine-learning model to predict storage capacities in water reservoirs, during a training phase, according to an embodiment;

FIG. 4 illustrates a process for operating a machine-learning model to predict storage capacities in water reservoirs, during an operation phase, according to an embodiment;

FIG. 5 illustrates a process for validating a machine-learning model, according to an embodiment; and

FIG. 6 illustrates the architecture of a machine-learning model, according to an embodiment.

### DETAILED DESCRIPTION

In an embodiment, systems, methods, and non-transitory computer-readable media are disclosed for AI-based prediction of storage capacities in water reservoirs. After reading this description, it will become apparent to one skilled in the art how to implement the invention in various alternative embodiments and alternative applications. However, although various embodiments of the present invention will be described herein, it is understood that these embodiments are presented by way of example and illustration only, and not limitation. As such, this detailed description of various embodiments should not be construed to limit the scope or breadth of the present invention as set forth in the appended claims.

### 1. Example Infrastructure

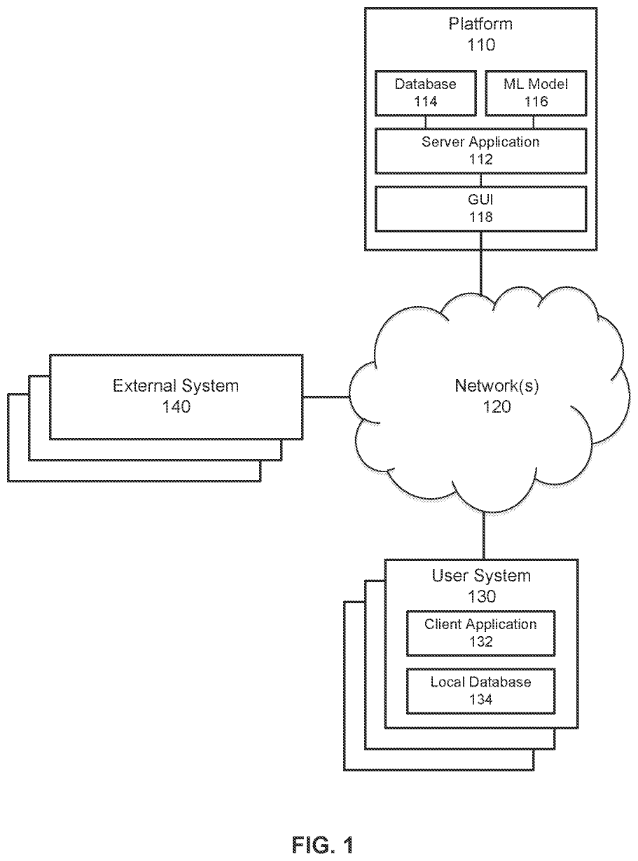

FIG. 1 illustrates an example infrastructure in which one or more of the disclosed processes may be implemented, according to an embodiment. The infrastructure may comprise a platform 110 (e.g., one or more servers) which hosts and/or executes one or more of the various processes described herein (e.g., implemented as methods or functions in one or more software modules). Platform 110 may comprise dedicated servers, or may instead be implemented in a computing cloud, in which the resources of one or more servers are dynamically and elastically allocated to multiple tenants based on demand. In either case, the servers may be collocated and/or geographically distributed. Platform 110 may comprise or be communicatively connected to a server application 112, which has access to a database 114, and/or has access to or comprises a machine-learning (ML) model 116. Server application 112 may also provide a graphical user interface (GUI) 118. In addition, platform 110 may be communicatively connected, via one or more networks 120, to one or more user systems 130 and/or one or more external systems 140 (e.g., other platforms, websites, etc.).

Network(s) 120 may comprise the Internet, and platform 110 may communicate with user system(s) 130 through the Internet using standard transmission protocols, such as HyperText Transfer Protocol (HTTP), HTTP Secure (HTTPS), File Transfer Protocol (FTP), FTP Secure (FTPS), Secure Shell FTP (SFTP), and the like, as well as proprietary protocols. While platform 110 is illustrated as being connected to various systems through a single set of network(s) 120, it should be understood that platform 110 may be connected to the various systems via different sets of one or more networks. For example, platform 110 may be connected to a subset of user systems 130 and/or external systems 140 via the Internet, but may be connected to one or more other user systems 130 and/or external systems 140 via an intranet. Furthermore, while only a few user systems 130 and external systems 140, one server application 112, one database 114, and one machine-learning model 116 are illustrated, it should be understood that the infrastructure may comprise any number of user systems 130, external systems, 140 server applications 112, databases 114, and machine-learning models 116.

User system(s) 130 may comprise any type or types of computing devices capable of wired and/or wireless communication, including without limitation, desktop computers, laptop computers, tablet computers, smart phones or other mobile phones, servers, game consoles, televisions, set-top boxes, electronic kiosks, point-of-sale terminals, and/or the like. However, it is generally contemplates that user system 130 would be the personal computer or workstation of either a developer of machine-learning model 116, operator of platform 110, or an end-user of machine-learning model 116 on platform 110. An end-user may be, for example, a water-resource manager for one or more communities whose water supply is affected by one or more water reservoirs. Each user system 130 may comprise or be communicatively connected to a client application 132 and/or one or more local databases 134.

Platform 110 may comprise web servers which host one or more websites and/or web services. In embodiments in which a website is provided, the website may comprise graphical user interface 118. Graphical user interface 118 may comprise one or more screens (e.g., webpages) generated in HyperText Markup Language (HTML) or other language. Platform 110 transmits or serves one or more screens of graphical user interface 118 in response to requests from user system(s) 130. In some embodiments, these screens may be served in the form of a wizard, in which case two or more screens may be served in a sequential manner, and one or more of the sequential screens may depend on an interaction of the user with one or more preceding screens. The requests to platform 110 and the responses from platform 110, including the screens of graphical user interface 118, may both be communicated through network(s) 120, which may include the Internet, using standard communication protocols (e.g., HTTP, HTTPS, etc.). These screens (e.g., webpages) may comprise a combination of content and elements, such as text, images, videos, animations, references (e.g., hyperlinks), frames, inputs (e.g., textboxes, text areas, checkboxes, radio buttons, drop-down menus, buttons, forms, etc.), scripts (e.g., JavaScript), and the like, including elements comprising or derived from data stored in one or more databases (e.g., database 114) that are locally and/or remotely accessible to platform 110.

Platform 110 may comprise, be communicatively coupled with, or otherwise have access to database 114. For example, platform 110 may comprise one or more database servers which manage database 114. Server application 112 executing on platform 110 and/or client application 132 executing on user system 130 may submit data (e.g., user data, form data, etc.) to be stored in database 114, and/or request access to data stored in database 114. Any suitable database may be utilized, including without limitation MySQL™, Oracle™, IBM™, Microsoft SQL™, Access™, PostgreSQL™, MongoDB™, and the like, including cloud-based databases and proprietary databases. Data may be sent to platform 110, for instance, using the well-known POST request supported by HTTP, via FTP, and/or the like. This data, as well as other requests, may be handled, for example, by server-side web technology, such as a servlet or other software module (e.g., comprised in server application 112), executed by platform 110.

In embodiments in which a web service is provided, platform 110 may receive requests from user system(s) 130 and/or external system(s) 140, and provide responses in eXtensible Markup Language (XML), JavaScript Object Notation (JSON), and/or any other suitable or desired format. In such embodiments, platform 110 may provide an application programming interface (API) which defines the manner in which user system(s) 130 and/or external system(s) 140 may interact with the web service. Thus, user system(s) 130 and/or external system(s) 140 (which may themselves be servers), can define their own user interfaces, and rely on the web service to implement or otherwise provide the backend processes, storage, and/or the like, described herein. For example, in such an embodiment, a client application 132, executing on one or more user system(s) 130, may interact with a server application 112 executing on platform 110 to execute one or more or a portion of one or more of the various processes described herein.

Client application 132 may be “thin,” in which case processing is primarily carried out server-side by server application 112 on platform 110. A basic example of a thin client application 132 is a browser application, which simply requests, receives, and renders webpages of graphical user interface 118 at user system(s) 130, while server application 112 on platform 110 is responsible for generating graphical user interface 118 and managing database functions. Alternatively, the client application may be “thick,” in which case processing is primarily carried out client-side by user system(s) 130. It should be understood that client application 132 may perform an amount of processing, relative to server application 112 on platform 110, at any point along this spectrum between “thin” and “thick,” depending on the design goals of the particular implementation. In any case, the software described herein, which may wholly reside on either platform 110 (e.g., in which case server application 112 performs all processing) or user system(s) 130 (e.g., in which case client application 132 performs all processing) or be distributed between platform 110 and user system(s) 130 (e.g., in which case server application 112 and client application 132 both perform processing), can comprise one or more executable software modules comprising instructions that implement one or more of the processes described herein.

### 2. Example Processing System

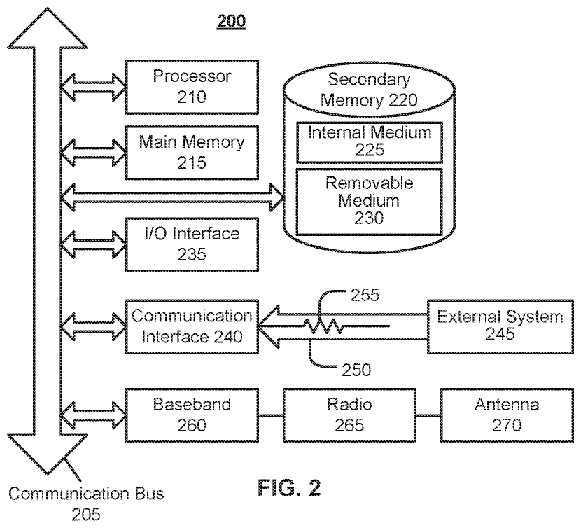

FIG. 2 is a block diagram illustrating an example wired or wireless system 200 that may be used in connection with various embodiments described herein. For example, system 200 may be used as or in conjunction with one or more of the processes (e.g., to store and/or execute the implementing software) described herein, and may represent components of platform 110, user system(s) 130, external system(s) 140, and/or other processing devices described herein. System 200 can be any processor-enabled device (e.g., server, personal computer, etc.) that is capable of wired or wireless data communication. Other processing systems and/or architectures may also be used, as will be clear to those skilled in the art.

System 200 may comprise one or more processors 210. Processor(s) 210 may comprise a central processing unit (CPU). Additional processors may be provided, such as a graphics processing unit (GPU), an auxiliary processor to manage input/output, an auxiliary processor to perform floating-point mathematical operations, a special-purpose microprocessor having an architecture suitable for fast execution of signal-processing algorithms (e.g., digital-signal processor), a subordinate processor (e.g., back-end processor), an additional microprocessor or controller for dual or multiple processor systems, and/or a coprocessor. Such auxiliary processors may be discrete processors or may be integrated with a main processor 210. Examples of processors which may be used with system 200 include, without limitation, any of the processors (e.g., Pentium™, Core i7™, Core i9™, Xeon™, etc.) available from Intel Corporation of Santa Clara, California, any of the processors available from Advanced Micro Devices, Incorporated (AMD) of Santa Clara, California, any of the processors (e.g., A series, M series, etc.) available from Apple Inc. of Cupertino, any of the processors (e.g., Exynos™) available from Samsung Electronics Co., Ltd., of Seoul, South Korea, any of the processors available from NXP Semiconductors N.V. of Eindhoven, Netherlands, and/or the like.

Processor(s) 210 may be connected to a communication bus 205. Communication bus 205 may include a data channel for facilitating information transfer between storage and other peripheral components of system 200. Furthermore, communication bus 205 may provide a set of signals used for communication with processor 210, including a data bus, address bus, and/or control bus (not shown). Communication bus 205 may comprise any standard or non-standard bus architecture such as, for example, bus architectures compliant with industry standard architecture (ISA), extended industry standard architecture (EISA), Micro Channel Architecture (MCA), peripheral component interconnect (PCI) local bus, standards promulgated by the Institute of Electrical and Electronics Engineers (IEEE) including IEEE 488 general-purpose interface bus (GPIB), IEEE 696/5-100, and/or the like.

System 200 may comprise main memory 215. Main memory 215 provides storage of instructions and data for programs executing on processor 210, such as any of the software discussed herein. It should be understood that programs stored in the memory and executed by processor 210 may be written and/or compiled according to any suitable language, including without limitation C/C++, Java, JavaScript, Perl, Python, Visual Basic, .NET, and the like. Main memory 215 is typically semiconductor-based memory such as dynamic random access memory (DRAM) and/or static random access memory (SRAM). Other semiconductor-based memory types include, for example, synchronous dynamic random access memory (SDRAM), Rambus dynamic random access memory (RDRAM), ferroelectric random access memory (FRAM), and the like, including read only memory (ROM).

System 200 may comprise secondary memory 220. Secondary memory 220 is a non-transitory computer-readable medium having computer-executable code and/or other data (e.g., the disclosed software) stored thereon. In this description, the term “computer-readable medium” is used to refer to any non-transitory computer-readable storage media used to provide computer-executable code and/or other data to or within system 200. The computer software stored on secondary memory 220 is read into main memory 215 for execution by processor 210. Secondary memory 220 may include, for example, semiconductor-based memory, such as programmable read-only memory (PROM), erasable programmable read-only memory (EPROM), electrically erasable read-only memory (EEPROM), and flash memory (block-oriented memory similar to EEPROM).

Secondary memory 220 may include an internal medium 225 and/or a removable medium 230. Internal medium 225 and removable medium 230 are read from and/or written to in any well-known manner. Internal medium 225 may comprise one or more hard disk drives, solid state drives, and/or the like. Removable storage medium 230 may be, for example, a magnetic tape drive, a compact disc (CD) drive, a digital versatile disc (DVD) drive, other optical drive, a flash memory drive, and/or the like.

System 200 may comprise an input/output (I/O) interface 235. I/O interface 235 provides an interface between one or more components of system 200 and one or more input and/or output devices. Example input devices include, without limitation, sensors, keyboards, touch screens or other touch-sensitive devices, cameras, biometric sensing devices, computer mice, trackballs, pen-based pointing devices, and/or the like. Examples of output devices include, without limitation, other processing systems, cathode ray tubes (CRTs), plasma displays, light-emitting diode (LED) displays, liquid crystal displays (LCDs), printers, vacuum fluorescent displays (VFDs), surface-conduction electron-emitter displays (SEDs), field emission displays (FEDs), and/or the like. In some cases, an input and output device may be combined, such as in the case of a touch panel display (e.g., in a smartphone, tablet computer, or other mobile device).

System 200 may comprise a communication interface 240. Communication interface 240 allows software to be transferred between system 200 and external devices (e.g. printers), networks, or other information sources. For example, computer-executable code and/or data may be transferred to system 200 from a network server (e.g., platform 110) via communication interface 240. Examples of communication interface 240 include a built-in network adapter, network interface card (NIC), Personal Computer Memory Card International Association (PCMCIA) network card, card bus network adapter, wireless network adapter, Universal Serial Bus (USB) network adapter, modem, a wireless data card, a communications port, an infrared interface, an IEEE 1394 fire-wire, and any other device capable of interfacing system 200 with a network (e.g., network(s) 120) or another computing device. Communication interface 240 preferably implements industry-promulgated protocol standards, such as Ethernet IEEE 802 standards, Fiber Channel, digital subscriber line (DSL), asynchronous digital subscriber line (ADSL), frame relay, asynchronous transfer mode (ATM), integrated digital services network (ISDN), personal communications services (PCS), transmission control protocol/Internet protocol (TCP/IP), serial line Internet protocol/point to point protocol (SLIP/PPP), and so on, but may also implement customized or non-standard interface protocols as well.

Software transferred via communication interface 240 is generally in the form of electrical communication signals 255. These signals 255 may be provided to communication interface 240 via a communication channel 250 between communication interface 240 and an external system 245 (e.g., which may correspond to an external system 140, an external computer-readable medium, and/or the like). In an embodiment, communication channel 250 may be a wired or wireless network (e.g., network(s) 120), or any variety of other communication links. Communication channel 250 carries signals 255 and can be implemented using a variety of wired or wireless communication means including wire or cable, fiber optics, conventional phone line, cellular phone link, wireless data communication link, radio frequency (“RF”) link, or infrared link, just to name a few.

Computer-executable code is stored in main memory 215 and/or secondary memory 220. Computer-executable code can also be received from an external system 245 via communication interface 240 and stored in main memory 215 and/or secondary memory 220. Such computer-executable code, when executed, enables system 200 to perform the various processes of the disclosed embodiments.

In an embodiment that is implemented using software, the software may be stored on a computer-readable medium and initially loaded into system 200 by way of removable medium 230, I/O interface 235, or communication interface 240. In such an embodiment, the software is loaded into system 200 in the form of electrical communication signals 255. The software, when executed by processor 210, preferably causes processor 210 to perform one or more of the processes and functions described elsewhere herein.

System 200 may comprise wireless communication components that facilitate wireless communication over a voice network and/or a data network (e.g., in the case of user system 130). The wireless communication components comprise an antenna system 270, a radio system 265, and a baseband system 260. In system 200, radio frequency (RF) signals are transmitted and received over the air by antenna system 270 under the management of radio system 265.

In an embodiment, antenna system 270 may comprise one or more antennae and one or more multiplexors (not shown) that perform a switching function to provide antenna system 270 with transmit and receive signal paths. In the receive path, received RF signals can be coupled from a multiplexor to a low noise amplifier (not shown) that amplifies the received RF signal and sends the amplified signal to radio system 265.

In an alternative embodiment, radio system 265 may comprise one or more radios that are configured to communicate over various frequencies. In an embodiment, radio system 265 may combine a demodulator (not shown) and modulator (not shown) in one integrated circuit (IC). The demodulator and modulator can also be separate components. In the incoming path, the demodulator strips away the RF carrier signal leaving a baseband receive audio signal, which is sent from radio system 265 to baseband system 260.

If the received signal contains audio information, then baseband system 260 decodes the signal and converts it to an analog signal. Then the signal is amplified and sent to a speaker. Baseband system 260 also receives analog audio signals from a microphone. These analog audio signals are converted to digital signals and encoded by baseband system 260. Baseband system 260 also encodes the digital signals for transmission and generates a baseband transmit audio signal that is routed to the modulator portion of radio system 265. The modulator mixes the baseband transmit audio signal with an RF carrier signal, generating an RF transmit signal that is routed to antenna system 270 and may pass through a power amplifier (not shown). The power amplifier amplifies the RF transmit signal and routes it to antenna system 270, where the signal is switched to the antenna port for transmission.

Baseband system 260 is communicatively coupled with processor(s) 210, which have access to memory 215 and 220. Thus, software can be received from baseband processor 260 and stored in main memory 210 or in secondary memory 220, or executed upon receipt. Such software, when executed, can enable system 200 to perform the various processes of the disclosed embodiments.

### 3. Introduction

There has been rapid growth in the use of AI-based technologies for water infrastructure and water-management systems, as discussed in Mehmood et al., “A review of artificial intelligence applications to achieve water-related sustainable development goals,” pp. 135-141, 2020, doi: 10.1109/AI4G50087.2020.9311018, and Niknam et al., “A critical review of short-term water demand forecasting tools—what method should I use?,” Sustainability (Switzerland), 14(9), 2022, doi: 10.3390/sul4095412, which are both hereby incorporated herein by reference as if set forth in full. However, AI-based solutions for water-resource management have generally focused on forecasting water demand and typically cater to water utility companies. See, e.g., Antunes et al., “Short-term water demand forecasting using machine learning techniques,” Journal of Hydroinformatics, 20(6):1343-1366, 2018, doi: 10.2166/hydro. 2018.163, which is hereby incorporated herein by reference as if set forth in full.

In addition, existing water-reservoir management strategies tend to be reactive to local weather conditions, as outlined by Tounsi et al., “On the use of machine learning to account for reservoir management rules and predict streamflow,” Neural Computing and Applications, pp. 1-15, 2022, which is hereby incorporated herein by reference as if set forth in full. Forecasting solutions, such as those developed by Tounsi et al. and Shiri et al., “Prediction of water-level in the Urmia lake using the extreme learning machine approach,” Water Resources Management, 30(14):5217-5229, 2016, which is hereby incorporated herein by reference as if set forth in full, allow for more proactive reservoir-management strategies. In particular, better forecasts of water levels in water reservoirs improve a water-resource manager's ability to plan for extreme climate events, such as droughts and floods.

Existing prediction models for water levels use statistical techniques to predict future water levels in a water reservoir. A common implementation involves the Autoregressive Integrated Moving Average (ARIMA) family of models. ARIMA models enhance the investigation of time series data by comparing data against time-lagged versions of itself. Sabzi et al., “Integration of time series forecasting in a dynamic decision support system for multiple reservoir management to conserve water sources,” Korean Society of Civil Engineers Journal of Civil Engineering, 20(2), 2016, which is hereby incorporated herein by reference as if set forth in full, utilizes a set of ARIMA models to predict reservoir inflow and develop operations strategies for water reservoirs in southern New Mexico. Similarly, Valipour et al., “Parameters estimate of autoregressive moving average and autoregressive integrated moving average models and compare their ability for inflow forecasting,” Journal of Mathematics and Statistics, 8(3), 2012, which is hereby incorporated herein by reference as if set forth in full, describes models to predict inflow to Iranian water reservoirs, Patle et al., “Time series analysis of groundwater levels and projection of future trend,” Energy Sources, Part A: Recovery, Utilization, and Environmental Effects, 2015, which is hereby incorporated herein by reference as if set forth in full, describes models to analyze groundwater usage in Haryana, India, and Musarat et al., “Kabul river flow prediction using automated ARIMA forecasting: A machine learning approach,” Sustainability, 13(19):10720, 2021, which is hereby incorporated herein by reference as if set forth in full, describes models to forecast discharges on the Kabul River in Pakistan.

Technological advancements have contributed to the development of more intricate computational techniques for analyzing complex problems. Developments in fields, such as machine learning (ML), have shifted the burden of data analysis from manual, human-centric techniques towards automated, computerized techniques. Machine-learning methods allow for improved data analysis, particularly in situations where data are highly dimensional and exhibit few meaningful correlative patterns to the human mind. Machine learning also allows for faster model prototyping and development.

Niu et al., “Comparison of multiple linear regression, artificial neural network, extreme learning machine, and support vector machine in deriving operation rule of hydropower reservoir,” Water, 11(1), 2019, which is hereby incorporated herein by reference as if set forth in full, has demonstrated that machine-learning techniques outperform standard multiple linear regression when predicting reservoir levels in China. Similarly, Shamim et al., “A comparison of artificial neural networks (ANN) and local linear regression (LLR) techniques for predicting monthly reservoir levels,” Korean Society of Civil Engineers Journal of Civil Engineering, 20(2), 2016, which is hereby incorporated herein by reference as if set forth in full, demonstrated that localized linear machine-learning models are capable of predicting reservoir levels in Pakistan. Qie et al., “Comparison of machine learning models performance on simulating reservoir outflow: a case study of two reservoirs in Illinois, U.S.A.,” Journal of the American Water Resources Association, 2022, which is hereby incorporated herein by reference as if set forth in full, analyzed reservoir outflow for two sites in Illinois, and demonstrated promising results using statistical techniques. Machine-learning models are also frequently used to research water quality, including in recent studies described in Nguyen et al., “Comparing the performance of machine learning algorithms for remote and in situ estimations of chlorophyll-a content: a case study in the Tri An Reservoir, Vietnam,” Water Environment Research, 93(12), 2021, Deng et al., “Machine learning based marine water quality prediction for coastal hydro-environment management,” Journal of Environmental Management, 284, 2021, and Ewusi et al., “Modelling of total dissolved solids in water supply systems using regression and supervised machine learning approaches,” Applied Water Science, 11(2), 2021, which are all hereby incorporated herein by reference as if set forth in full.

One particular machine-learning algorithm is the artificial neural network (ANN), which was originally described in McCulloch et al., “A logical calculus of the ideas immanent in nervous activity,” The Bulletin of Mathematical Biophysics, 5(4), 1943, which is hereby incorporated herein by reference as if set forth in full. An artificial neural network is designed to mimic human brain function by implementing a series of logical decision gates, known as neurons, to analyze data. Different types of artificial neural networks can be formed by altering the decision function at each gate and/or the internal architecture of the artificial neural network. Das et al., “A probabilistic nonlinear model for forecasting daily water level in reservoir,” Water Resources Management, 30, 2016, which is hereby incorporated herein by reference as if set forth in full, applied Bayesian probabilistic analysis at each logic gate to produce an artificial neural network that outperformed both ARIMA models and traditional artificial neural networks for predictions at a reservoir in Jharkhand, India. Chang et al., “Adaptive neuro-fuzzy inference system for prediction of water level in reservoir,” Advances in Water Resources, 29(1), 2006, and Unes et al., “Prediction of dam reservoir volume fluctuations using adaptive neuro fuzzy approach,” European Journal of Engineering and Natural Sciences, 2(1), 2017, which are both hereby incorporated herein by reference as if set forth in full, implemented fuzzy logic at neural gates to achieve similar accuracy in predicting reservoir statuses in Taiwan and Turkey, respectively.

Continued research on artificial neural networks has led to the creation of specialized ANN structures for particular applications. One such structure is the recurrent neural network (RNN), which loops data through the artificial neural network multiple times before “forgetting” the data. These loops enable the analysis of recent history, which renders the recurrent neural network a useful tool for analyzing sequential data, such as time series data, as demonstrated by Hewamalage et al., “Recurrent neural networks for time series forecasting: Current status and future directions,” International Journal of Forecasting, 37(1), 2021, which is hereby incorporated herein by reference as if set forth in full.

To combat mathematical peculiarities that may arise during computation, Hochreiter et al., “Long short-term memory,” Neural Computation, 9(8), 1997, which is hereby incorporated herein by reference as if set forth in full, developed the long short-term memory (LSTM) extension to RNN theory. Zhang et al., “Simulating reservoir operation using a recurrent neural network algorithm,” Water, 11, 2019, which is hereby incorporated herein by reference as if set forth in full, demonstrated that RNN models that are enhanced with the LSTM extension outperformed other artificial neural networks in modeling reservoir outflow at a hydropower station on the Jinsha River in China. Similarly, Liu et al., “Ensemble streamflow forecasting over a cascade reservoir catchment with integrated hydrometeorological modeling and machine learning,” Hydrology and Earth System Sciences, 26(2), 2022, which is hereby incorporated herein by reference as if set forth in full, used long short-term memory to augment hydrological simulations to improve forecast accuracy of streamflow predictions at a hydropower station in Guangxi, China, by as much as 6%.

A common thread, linking existing research, is a focus on implementing one or more statistical techniques at a single station or drainage basin. Currently, there is no solution that can broadly model and predict storage capacities in water reservoirs, across multiple reservoirs and basins and across variations in climate. Accordingly, a machine-learning model 116, which may comprise an artificial neural network, such as a recurrent neural network, with long short-term memory, is disclosed. Machine-learning model 116 may be trained to predict storage capacities of water reservoirs from historical climate parameters about the watersheds of water reservoirs and from historical reservoir parameters of those water reservoirs. During training, machine-learning model 116 learns how to infer the storage capacity of a reservoir from the interactions between these climate and reservoir parameters. Experimental results, discussed elsewhere herein, demonstrate that machine-learning model 116 has a high level of predictive accuracy, so as to be beneficial for long-term water-management decisions.

### 4. Example Training

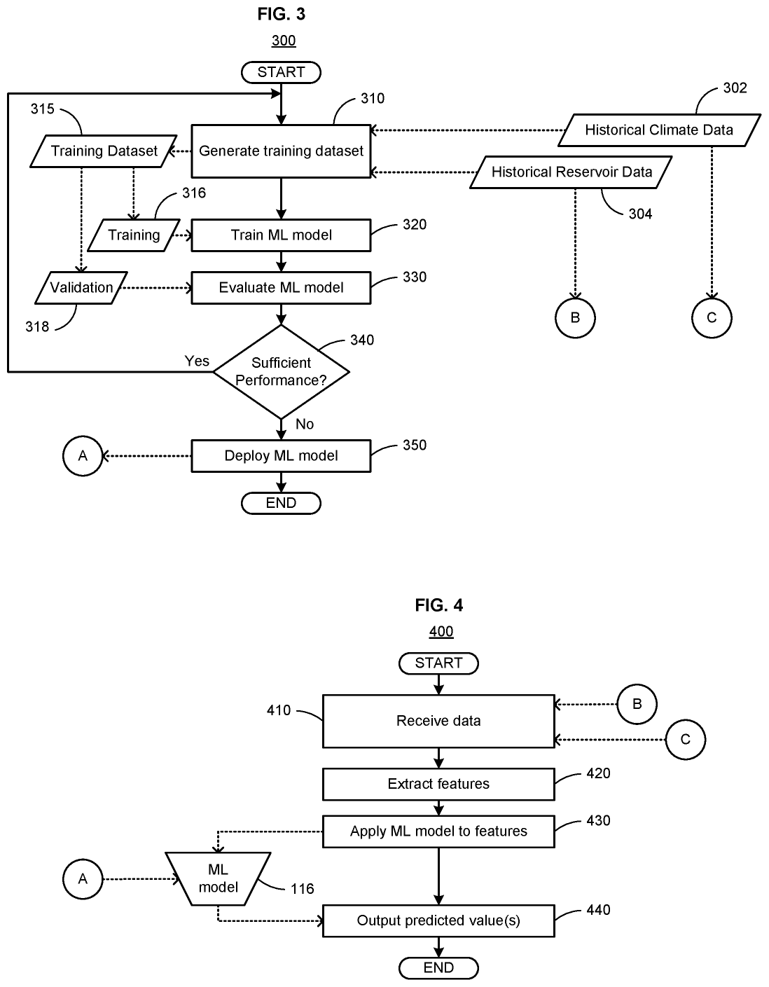

FIG. 3 illustrates a process 300 for training machine-learning model 116 to predict storage capacities in water reservoirs, during a training phase, according to an embodiment. It is generally contemplated that process 300 would be implemented by server application 112, executing on platform 110. However, process 300 could be implemented by any software, hardware, or combination of software and hardware. In any case, process 300 may be performed under the guidance of a developer, working on behalf of an operator of platform 110.

While process 300 is illustrated with a certain arrangement and ordering of subprocesses, process 300 may be implemented with fewer, more, or different subprocesses and a different arrangement and/or ordering of subprocesses. It should also be understood that any subprocess, which does not depend on the completion of another subprocess, may be executed before, after, or in parallel with that other independent subprocess, even if the subprocesses are described or illustrated in a particular order.

The input to process 300 may be historical climate (i.e., climatological) data 302 and/or historical reservoir (i.e., hydrological) data 304. Historical climate data 302 may comprise one or more climate parameters that are relevant to one or more water reservoirs. The climate parameters may be measured by one or more weather sensors in the geographical vicinity of each water reservoir, over time, so as to represent a time series of weather data affecting each water reservoir. The “geographical vicinity” of a water reservoir may comprise, consist, or approximate the watershed of that water reservoir, as well as the water reservoir itself. It should be understood that the “watershed” of a water reservoir is the area of land in which all flowing surface water converges to the water reservoir, and may also be referred to as a “drainage basin,” “drainage area,” “catchment basin,” “catchment area,” “water basin,” “impluvium,” or the like. In an embodiment, the climate parameter(s) comprise at least the temperature (e.g., in degrees Celsius or Fahrenheit) and precipitation (e.g., in millimeters, centimeters, or inches of rainfall, snowfall, etc.) in the geographical vicinity of the water reservoir. However, it should be understood that the climate parameter(s) may comprise any parameter that may be relevant to the water level in a water reservoir, including, without limitation, soil moisture, humidity, barometric pressure, solar insolation, wind speed, the presence of a weather alert (e.g., storm warning), and/or the like. Historical climate data 302 may comprise the value of each climate parameter for the geographical vicinity of each water reservoir at each of a plurality of past times. Historical climate data 302 may also comprise metadata for each climate parameter, such as the location (e.g., coordinates in the Global Positioning System (GPS) or other global navigation satellite system (GNSS)) at which the value of each climate parameter was measured.

Historical reservoir data 304 may comprise one or more reservoir parameters for the same one or more reservoirs represented in historical climate data 302. The reservoir parameters may be measured by one or more sensors in the water reservoir, over time, so as to represent a time series of reservoir data for each water reservoir. In an embodiment, the reservoir parameter(s) comprise at least the water level of each water reservoir. The water level of a water reservoir may be measured as a gage height of the water level in the water reservoir. Gage height measures the elevation of the water surface in the water reservoir above a fixed reference point at a stream-gaging station. Alternatively or additionally, the reservoir parameter(s) may comprise at least the storage (i.e., volume of water stored) or storage capacity (e.g., the difference in volume between the current storage and the maximum storage) of each water reservoir. As another example, the reservoir parameter(s) may comprise water inflow to the water reservoir and/or water outflow from the water reservoir. Historical reservoir data 304 may comprise the value of each reservoir parameter for each water reservoir at each of a plurality of past times. In an embodiment, historical reservoir data 304 may comprise or otherwise be derived from the reservoir elevation data published by the United States Geological Survey (USGS) for the USGS stream gage network. Historical reservoir data 304 may also comprise reservoir metadata, such as identifiers of each water reservoir, the location of each water reservoir (e.g., coordinates in GPS or other GNSS representing the location of each stream-gaging station and/or boundaries of the water reservoir), and/or the like.

It should be understood that storage and storage capacity are two sides of the same coin, and are easily convertible between each other based on a maximum storage of the water reservoir. In particular, the storage capacity can be calculated as the difference between the maximum storage and the current storage. This difference indicates how much more water can flow into the water reservoir before the water reservoir overflows. It should also be understood that the water level for a water reservoir can also be used to determine storage and/or storage capacity of the water reservoir based on a model of the water reservoir that maps the water level at the stream-gaging station to storage and/or storage capacity for the water reservoir.

In subprocess 310, a training dataset 315 is generated or otherwise acquired from historical climate data 302 and historical reservoir data 304. Training dataset 315 may comprise a plurality of labeled feature vectors. Each feature vector may contain the value of each of a plurality of features, derived from historical climate data 302 and historical reservoir data 304. In addition, each feature vector in training dataset 315 is labeled with a target, comprising the ground-truth value of at least one target parameter for that feature vector. The values of the plurality of features and/or target parameter(s) may be standardized and/or normalized (e.g., converted to common units of measure) when converting historical climate data 302 and/or historical reservoir data 304 into training dataset 315.

In an embodiment, the plurality of features comprises, for a given water reservoir, a time series of a plurality of tuples, with each tuple comprising a value for each of one or more climate parameters, derived from historical climate data 302, and one or more reservoir parameters, derived from historical reservoir data 304, for a respective water reservoir. For example, each tuple may comprise or consist of a value representing temperature derived from historical climate data 302, a value representing precipitation derived from historical climate data 302, and a value representing water level, water storage, or storage capacity derived from historical reservoir data 304 for the respective water reservoir. However, it should be understood that this is simply one example, and that additional or alternative features may be included in each tuple, including, without limitation, soil moisture from historical climate data 302, water inflow from historical reservoir data 304, water outflow from historical reservoir data 304, and/or the like.

The time series in each feature vector may comprise a tuple for each of a plurality of time intervals. In addition, each tuple in the time series may represent one time interval within a plurality of consecutive time intervals. As an example, each time interval may be a twenty-four-hour period. In this case, each tuple represents one day, and the time series represents a series of days. For instance, a time series representing two weeks and having a tuple for each twenty-four-hour period, would comprise or consist of fourteen tuples.

For each water reservoir, the climate parameter(s) for that water reservoir may be correlated to the reservoir parameter(s) for that water reservoir based on the location at which the value(s) of the climate parameter(s) were measured (e.g., as specified in the metadata of historical climate data 302) and the location of the water reservoir (e.g., as specified in the metadata of historical reservoir data 304). In some cases, the locations associated with climate parameters in historical climate data 302 may not correspond precisely to the location of a water reservoir. In this case, the value of each climate parameter for the water reservoir may be interpolated from the value(s) of each climate parameter for two or more locations within the geographical vicinity (e.g., watershed) of the water reservoir.

In an embodiment, historical climate data 302 comprise or consist of observed values of the climate parameter(s) (e.g., temperature and precipitation) that are spatially scattered in a non-uniform manner. In this case, these observed values may be mapped into a gridded dataset, by interpolating a value for each of a plurality of points in a uniform grid (e.g., a one-kilometer by one-kilometer grid). In other words, the gridded dataset may be derived by interpolating point-based observations across a uniform grid. As an example, the Parameter-elevation Regressions on Independent Slopes Model (PRISM), as described in Daly et al., “The PRISM climate and weather system—an introduction,” Corvallis, Oregon, PRISM climate group, 2, 2013, which is hereby incorporated herein by reference as if set forth in full, may be used to interpolate a value of each climate parameter for each point in a grid from the scattered observed values of climate parameters in historical climate data 302.

The interpolated values of the climate parameter(s) in the resulting grid can then be spatially aggregated into a value of each climate parameter for the geographical vicinity (e.g., watershed) of a given water reservoir based on the location of the water reservoir within the grid. Regardless of the model that is used, a single value for each climate parameter for a given water reservoir may be calculated from the values of that climate parameter at points in the grid that represent the geographical vicinity of the water reservoir (e.g., several points representing the boundaries of the watershed of the water reservoir and/or within the boundaries of the watershed of the water reservoir). The calculation may comprise a spatial average of the values of the climate parameter at the points, or any other suitable spatial aggregation. In other words, the value of each climate parameter for a water reservoir may be calculated by spatially aggregating a plurality of values of that climate parameter for at least a subset, of the plurality of points in the uniform grid, representing a geographical vicinity (e.g., watershed) of the water reservoir.

The target with which each feature vector is labeled may comprise the value of at least one target parameter for at least one subsequent time interval (i.e., a future time interval with respect to the time series in the feature vector, but not with respect to the time of training). The target parameter may be any parameter that is useful for water-resource management. In an embodiment, the target parameter is a storage parameter of the respective water reservoir, such as the water level of the respective water reservoir, a change in water level of the respective water reservoir, water storage in the respective water reservoir, a change in water storage in the respective water reservoir, a storage capacity of the respective water reservoir, a change in storage capacity of the respective water reservoir, or the like. It should be understood that each of these exemplary target parameters can be easily converted into any of the other exemplary target parameters, and therefore, the particular target parameter(s) that are used are not essential. The subsequent time interval(s) of the target may each have the same length as the time intervals in the time series in the feature vector. For example, if the time interval is one day (i.e., one twenty-four-hour period), the feature vector may comprise tuples for N days (e.g., N=14), and the target may comprise the value of the target parameter(s) for subsequent day N+M (e.g., M=1, M=7, M=14, M=30, etc.). In an embodiment, the target represents a value of the target parameter at a subsequent time interval that is at least two time intervals (i.e., M≥2) after the last time interval in the time series in the feature vector, and preferably at least seven time intervals (i.e., M≥7) after the last time interval in the time series in the feature vector. The target may consist of the value of the target parameter(s) for only a single subsequent time interval (e.g., day N+M only) or comprise the value of the target parameter(s) for each of a plurality of subsequent time intervals (e.g., day N+M, day N+M+1, day N+M+2, . . . day N+M+X). In a particular implementation, the feature vector consisted of a time series of fourteen days of tuples (i.e., N=14) and the target consisted of the value of each target parameter for one week (i.e., seven days) in the future (i.e., M=7) or two weeks (i.e., fourteen days) in the future (i.e., M=14) from the time series in the feature vector.

It should be understood that, if the observed values of the climate parameter(s) and/or reservoir parameter(s) in historical climate data 302 and/or historical reservoir data 304, respectively, are not aligned along the time interval used for the labeled feature vectors, these observed values may be resampled, so as to align with the time interval. For example, if observed values for a given parameter exist at one-hour intervals, and the time interval for the labeled feature vectors is twenty-four hours, the value of the parameter for the time interval may be derived as the observed value at a fixed hour (e.g., 12:00 pm, 12:00 am, etc.) in every twenty-four-hour period, an average of the observed values for the entire twenty-four-hour period, or the like. In the event that the observed values of a parameter have a lower resolution than the time interval for the labeled feature vectors, interpolation may be used to supply the value of the parameter for any time interval that does not contain a value of the parameter. In this case, the observed values of the parameters immediately preceding and immediately following the time interval may be used (e.g., averaged) to derive a value of the parameter. More generally, any missing values of any parameter in historical climate data 302 and/or historical reservoir data 304 may be interpolated (e.g., via linear interpolation).

Once generated, training dataset 315 may be split into one or more subsets, including a training subset 316 and a validation subset 318. Although not illustrated, training dataset 315 could also be split into a testing subset. Each subset comprises or consists of a portion of training dataset 315. The division of training dataset 315 into the various subsets may be performed sequentially (e.g., to form contiguous subsets of labeled feature vectors), in order to preserve autocorrelation of the data within each subset (e.g., training subset 316 and validation subset 318) of training dataset 315.

In subprocess 320, machine-learning model 116 is trained, using training subset 316 of training dataset 315, with supervised learning, to predict a value of each target parameter (e.g., storage parameter) for any of a plurality of water reservoirs. In particular, machine-learning model 116 may be trained by minimizing a loss function over a plurality of training iterations. In each training iteration, one feature vector from training dataset 315 may be input to machine-learning model 116 to output a predicted value of each target parameter, the loss function may calculate an error between the predicted value and the target value with which the feature vector is labeled, and one or more weights in machine-learning model 116 may be adjusted, according to a suitable technique (e.g., gradient descent), to reduce the error. A training iteration may be performed for each of the labeled feature vectors in training subset 316. In an embodiment, machine-learning model 116 is an artificial neural network, such as a recurrent neural network, with long short-term memory, as described in more detail elsewhere herein.

In subprocess 330, machine-learning model 116, trained in subprocess 320, may be evaluated. The evaluation may comprise validating machine-learning model 116 using validation subset 318 of training dataset 315. The evaluation may also comprise testing machine-learning model 116 using a testing subset of training dataset 315. The result of subprocess 330 may be a performance measure for machine-learning model 116, such as an accuracy of machine-learning model 116. In an embodiment, machine-learning model 116 is validated in subprocess 330 using hindcasting and/or forecasting, as will be described in greater detail elsewhere herein. However, evaluation of machine-learning model 116 in subprocess 330 may be performed in any suitable manner.

In subprocess 340, it is determined whether or not machine-learning model 116, trained in subprocess 320, is acceptable based on the evaluation performed in subprocess 330. For example, the performance measure from subprocess 340 may be compared to a threshold or one or more other criteria. If the performance measure satisfies the criteria (e.g., is greater than or equal to the threshold), machine-learning model 116 may be determined to be acceptable (i.e., “Yes” in subprocess 340). Conversely, if the performance measure does not satisfy the criteria (e.g., is less than the threshold), machine-learning model 116 may be determined to be unacceptable (i.e., “No” in subprocess 340). When machine-learning model 116 is determined to be acceptable (i.e., “Yes” in subprocess 340), process 300 may proceed to subprocess 350. Otherwise, when machine-learning model 116 is determined to be unacceptable (i.e., “No” in subprocess 340), process 300 may return to subprocess 310 to retrain machine-learning model 116 (e.g., using a new or modified training dataset 315).

In subprocess 350, the trained machine-learning model 116 may be deployed. In an embodiment, machine-learning model 116 receives the values of a plurality of features representing climate and/or reservoir parameters, and outputs a predicted value of each target parameter. In an embodiment, the plurality of features comprises a time series of N tuples, representing N consecutive time intervals, with each tuple comprising a value of one or more climate parameters (e.g., temperature and precipitation) and one or more reservoir parameters (e.g., water level, water storage, or storage capacity), and the target parameter(s) comprise or consist of the water level, change in water level, water storage, change in water storage, storage capacity, or change in storage capacity for subsequent time interval N+M (e.g., M=1, M=7, M=14, M=30, etc.). Machine-learning model 116 may be deployed by moving machine-learning model 116 from a development environment to a production environment of platform 110. For example, machine-learning model 116 may be made available at an address on platform 110 (e.g., in a microservice architecture) that is accessible to server application 112. Alternatively, machine-learning model 116 may be comprised in server application 112.

### 5. Example Operation

FIG. 4 illustrates a process 400 for operating machine-learning model 116 to predict storage capacities in water reservoirs, during an operation phase, according to an embodiment. It is generally contemplated that process 400 would be implemented by server application 112, executing on platform 110, or as a service that is accessible to server application 112. However, process 400 could be implemented by any software, hardware, or combination of software and hardware.

While process 400 is illustrated with a certain arrangement and ordering of subprocesses, process 400 may be implemented with fewer, more, or different subprocesses and a different arrangement and/or ordering of subprocesses. It should also be understood that any subprocess, which does not depend on the completion of another subprocess, may be executed before, after, or in parallel with that other independent subprocess, even if the subprocesses are described or illustrated in a particular order.

Initially, in subprocess 410, historical climate data 302 and/or historical reservoir data 304 may be received for a water reservoir of interest. Historical climate data 302 may be the same as discussed above with respect to process 300, and historical reservoir data 304 may be the same data as discussed above with respect to process 300. However, it should be understood that the historical climate data 302 and historical reservoir data 304 that are used during operation may comprise or consist of more recent observations than the historical climate data 302 and historical reservoir data 304 used to generate training dataset 315, and for a specific water reservoir of interest, rather than a plurality of diverse water reservoirs. In particular, during operation, historical climate data 302 and historical reservoir data 304 may comprise observed values of the climate and reservoir parameters, respectively, for the most recent past N days for a specific water reservoir, whereas for training, historical climate data 302 and historical reservoir data 304 may comprise observed values of the climate and reservoir parameters, respectively, for at least N+M days in the past and generally much further into the past (e.g., two or more years into the past), and for a plurality of geographically diverse water reservoirs.

In subprocess 420, the value of each of the plurality of features may be extracted from the data received in subprocess 410. The values of the plurality of features may be extracted in the same manner as they were extracted in subprocess 310 to generate the feature vectors in training dataset 315. In other words, a feature vector, comprising the values of the plurality of features, may be generated in subprocess 420, from the data received in subprocess 410, in the same manner as the labeled feature vectors were generated in subprocess 310, except without the labels. As discussed with respect to subprocess 310, the plurality of features may comprise or consist of a time series of N tuples, with each tuple comprising one or more climate parameters from historical climate data 302 and/or one or more reservoir parameters from historical reservoir data 304 for one of a plurality of time intervals that collectively represent the most recent past N time intervals. In an embodiment, each tuple comprises, for one of N successive time intervals, the temperature, precipitation, and water level, water storage, or storage capacity for the water reservoir of interest for which the target parameter(s) are to be predicted. Alternatively or additionally, each tuple may comprise other climate and/or reservoir parameters, such as soil moisture, water inflow, water outflow, and/or the like.

In subprocess 430, machine-learning model 116, which was trained in subprocess 320 of process 300 and deployed by subprocess 350 of process 300, may be applied to the plurality of features, extracted in subprocess 420. In particular, a feature vector, comprising the time series of tuples, may be input to machine-learning model 116. When applied to such a feature vector, machine-learning model 116 may predict the value of the target parameter(s) for a single future time interval (e.g., time interval N+M, in which M≥1, such as M=1, M=7, M=14, M=30, etc.) for the water reservoir of interest. Alternatively, machine-learning model 116 may predict the value of the target parameter(s) for a plurality of future time intervals (e.g., time intervals N+M, N+M+1, . . . , N+M+X, such as X=6, X=13, etc.) for the water reservoir of interest.

In subprocess 440, the output of machine-learning model 116, comprising or consisting of the value of the target parameter(s) (e.g., water level, change in water level, water storage, change in water storage, storage capacity, change in storage capacity, etc.) for the water reservoir of interest for each of one or more future time intervals, may be output to one or more downstream functions. These downstream functions may comprise one or more tools for water-resource management that are utilized to produce manual decisions (e.g., by a water-resource manager), automated decisions (e.g., without intervention from a water-resource manager), or semi-automated decisions (e.g., with approval from a water-resource manager) about whether or not to take one or more actions with respect to the water reservoir of interest.

These action(s) may comprise releasing water stored in the water reservoir, implementing one or more conservation practices, purchasing water for a community served by the water reservoir, and/or the like. For example, if the water storage in the water reservoir is predicted to exceed the maximum storage capacity of the water reservoir (i.e., overflow the water reservoir, which risks flooding to the community) in M time intervals, water can be released from the water reservoir in advance of the M-th time interval (e.g., for irrigation in surrounding agricultural sites), in order to prevent or otherwise mitigate flood damage. As another example, if the water storage in the water reservoir is predicted to drop below the dead pool storage of the water reservoir (i.e., representing water that cannot be released from the water reservoir) in M time intervals, one or more conservation practices can be implemented and/or water can be purchased to ensure that community needs are satisfied. As yet another example, the predicted water storage in the water reservoir can be used to determine whether or not to purchase water in future time intervals for those communities that purchase water.

More generally, the predictive output of machine-learning model 116, which comprises or is otherwise indicative of the storage capacity of a water reservoir of interest, can be used in any area of water conservation and/or usage. The predictive output can benefit conservation planning in the event of an impending drought, or water discharge planning (e.g., for irrigation purposes) in the event of an impending heavy rainfall event. The agricultural industry may benefit from this predictive planning, as irrigation and farming represent a major portion of reservoir usage. In addition, energy companies that draw water from and release water into water reservoirs can benefit from predictive and preemptive water planning. Furthermore, water districts that make decisions, such as water purchasing for local governments and counties, can use the predictive outputs of machine-learning model 116 to plan their water purchasing decisions. Similarly, bottling companies and water-treatment plants that draw water from water reservoirs can better plan their water usage activities, based on the outputs of machine-learning model 116.

### 6. Example Validation

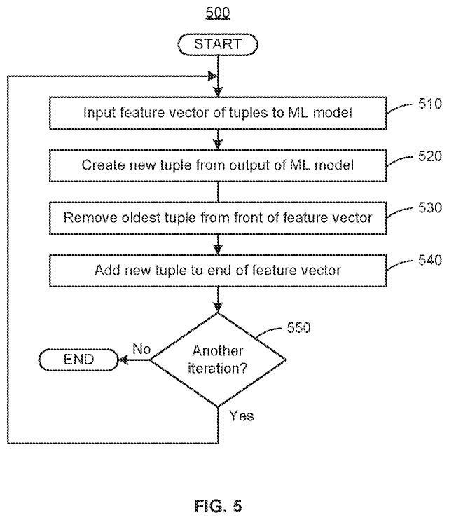

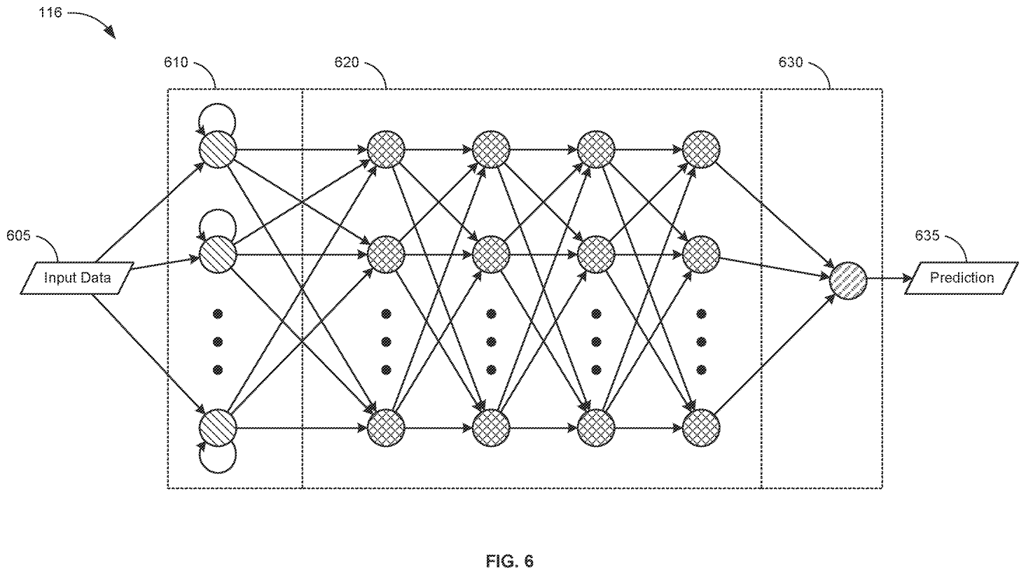

FIG. 5 illustrates a process 500 for validating machine-learning model 116, according to an embodiment. It is generally contemplated that process 500 would be implemented by server application 112, executing on platform 110. However, process 500 could be implemented by any software, hardware, or combination of software and hardware. In any case, process 500 may be performed, as part of subprocess 330, under the guidance of a developer, working on behalf of an operator of platform 110.

While process 500 is illustrated with a certain arrangement and ordering of subprocesses, process 500 may be implemented with fewer, more, or different subprocesses and a different arrangement and/or ordering of subprocesses. It should also be understood that any subprocess, which does not depend on the completion of another subprocess, may be executed before, after, or in parallel with that other independent subprocess, even if the subprocesses are described or illustrated in a particular order.

Process 500 may be performed in subprocess 330 of process 300 for each of a plurality of feature vectors in validation subset 318. In subprocess 510, one of the feature vectors in validation subset 318 is input to machine-learning model 116. As discussed elsewhere, the feature vector may comprise a time series of N tuples (e.g., N=14), with each tuple representing one of a plurality of consecutive time intervals and the tuples arranged in chronological order. Each tuple may comprise the historical temperature, precipitation, and water level, water storage, or storage capacity of a water reservoir during the respective time interval. Thus, for example, the initial feature vector may be represented as F₁=[(t₁, p₁, s₁), (t₂, p₂, s₂), . . . (t_{N-1}, p_{N-1}, s_{N-1}) (t_{N}, p_{N}, s_{N})], in which tᵢ is the temperature in in the i-th time interval, pᵢ is the precipitation in the i-th time interval, and sᵢ is the target parameter (e.g., storage parameter, such as water level, change in water level, water storage, change in water storage, storage capacity, change in storage capacity, etc.) of the water reservoir in the i-th time interval. It should be understood that this is simply one example of a feature vector, and that each tuple could comprise one or more additional or alternative parameters, such as soil moisture, water inflow, water outflow, and/or the like.

The result of subprocess 510 will be a predicted value of each target parameter(s), such as water level, change in water level, water storage, change in water storage, storage capacity, or change in storage capacity of a water reservoir represented by the feature vector, during at least one subsequent time interval. For simplicity of explanation, it will be assumed that the reservoir parameter in the tuples of the feature vector consists of storage capacity, that the target parameter consists of storage capacity, and that machine-learning model 116 predicts the value of the storage capacity for a single subsequent time interval. In this case, if feature vector F₁ is used as the input, machine-learning model 116 would predict storage capacity s_{N+1} for the N+1-th time interval.

In subprocess 520, a new tuple is created from the output of machine-learning model 116 in subprocess 510. Continuing the example above, a tuple (t_{N+1}, p_{N+1}, s_{N+1}) is created, in which s_{N+1} is the predicted value of the target parameter output by machine-learning model 116. If the values of the climate parameters, such as t_{N+1} and p_{N+1} in this example, are included in or otherwise derivable from historical climate data 302, the values of the climate parameters may be inserted. This method of determining the climate parameters in subprocess 520 is referred to as “hindcasting.” Alternatively, if the values of the climate parameters, such as t_{N+1} and p_{N+1} in this example, are not included in or otherwise derivable from historical climate data 302 (e.g., because time interval N+1 is in the future), the values of the climate parameters may be forecasted. This method of determining the climate parameters in subprocess 520 is referred to as “forecasting.” In this case, the climate parameters may be forecasted using any suitable means, such as by retrieving or otherwise acquiring a weather forecast of one or more national weather services or other weather forecast models for the future time interval. Examples of weather forecast models include, without limitation, the Global Forecast System (GFS) model, the European Center for Medium-Range Weather Forecasts (ECMWF) model, the Icosahedral Nonhydrostatic (ICON) weather and climate model, the Global Environmental Multiscale Model (GEM), the Navy Global Environmental Model (NAVGEM), and the like. Regardless of whether hindcasting or forecasting is used, the new tuple is supplied with values of the climate parameters, such as t_{N+1} and p_{N+1} in this example.

In subprocess 530, the oldest tuple from the feature vector is removed from the front of the feature vector. Continuing the example above, in the first iteration of subprocess 530, the tuple (t₁, p₁, s₁) would be removed to produce an intermediate feature vector of [t₂, p₂, s₂), . . . (t_{N-1}, p_{N-1}, s_{N-1}) (t_{N} p_{N}, s_{N})]. Similarly, in the second iteration of subprocess 530, the tuple (t₂, p₂, s₂) would be removed, and so on and so forth.

In subprocess 540, the new tuple, created in subprocess 520, is added to the end of the feature vector. Continuing the example above, the tuple (t_{N+1}, p_{N+1}, s_{N+1}) is added to the end of the intermediate feature vector created in subprocess 530, to produce a feature vector F₂=[(t₂, p₂, s₂), (t₃, p₃, s₃), . . . (t_{N}, p_{N}, s_{N}), (t_{N+1}, p_{N+1}, s_{N+1})]. Like the initial feature vector F₁, the new feature vector F₂ has the same number N of tuples, but the time intervals, represented by the tuples, have been shifted forward by one time interval.

In subprocess 550, it is determined whether or not to perform another iteration. This determination may be based on one or more criteria. In an embodiment, a fixed number Y of iterations (e.g., Y=16) are performed. In this case, subprocess 550 could maintain a counter, which is incremented each time an iteration of subprocess 550 is executed, and determine that another iteration is to be performed whenever the counter is less than or equal to a predefined threshold (e.g., Y=16). When no more iterations are to be performed (i.e., “No” in subprocess 550), process 500 may end. When another iteration is to be performed (i.e., “Yes” in subprocess 550), process 500 may return to subprocess 510 to perform the next iteration.

Over all iterations within an execution of process 500, a set of feature vectors F₁, F₂, . . . F_{Y} will be produced. Each feature vector F₁, F₂, . . . F_{Y} will consist of a time series of exactly N tuples, representing N consecutive time intervals. Feature vector F₁ will consist of tuples that are all based on historical data, whereas the remaining feature vectors F₂, . . . F_{Y} will each have at least one tuple that comprises a predicted value of the target parameter (e.g., s), and either historical or forecasted values of the climate parameters (e.g., t and p), depending on whether hindcasting or forecasting was used in subprocess 520.

The set of feature vectors F₁, F₂, . . . F_{Y} can be evaluated in subprocess 330 of process 300 to identify and correct biases in machine-learning model 116. In particular, an analysis of the sets of feature vectors produced by executions of process 500 can identify a consistent bias by machine-learning model 116 to over-predict or under-predict. Over the course of Y prediction periods, the prediction errors will become evident due to compounding, such that any bias can be easily identified. For example, if machine-learning model 116 is biased towards over-prediction, the residual errors, produced by process 500, will be biased towards over-prediction. With sufficient samples (e.g., seven-hundred-thirty samples using a daily time interval for two years of data), any bias in machine-learning model 116 will be evident.

### 7. Example Architecture of Machine-Learning Model

FIG. 6 illustrates the architecture of machine-learning model 116, according to an embodiment. As illustrated, machine-learning model 116 may be a deep-learning artificial neural network (DNN), such as a recurrent neural network (RNN) with long short-term memory (LSTM), that processes input data 605 to produce a prediction 635. Machine-learning model 116 may comprise, in order from input data 605 to prediction 635, an LSTM structure 610, a densely connected structure 620, and an aggregation node 630.

As discussed elsewhere herein, input data 605 may comprise a feature vector. The feature vector may comprise a time series of chronologically ordered tuples, with each tuple representing one of a plurality of consecutive time intervals within a past time window of N time intervals (e.g., N=14). For example, the feature vector may be represented as F=[(t_{-N}, p_{-N}, s_{-N}), (t_{-N-1}), p_{-(N-1)}, s_{-(N-1)}), . . . (t₋₂, p₋₂, s₋₂), (t₋₁, p₋₁, s₋₁)], in which tᵢ is the temperature in in the i-th time interval, pᵢ is the precipitation in the i-th time interval, and sᵢ is a storage or other reservoir parameter of the water reservoir in the i-th time interval. Notably, the time intervals for the feature vector in input data 605, may start from N time intervals in the past from the current time (e.g., two weeks ago if N=14 and the time intervals are days) and end with the most recent past time interval (e.g., yesterday if the time intervals are days).

Input data 605 is input to LSTM structure 610 of machine-learning model 116. In an embodiment, LSTM structure 610 consists of a single layer of Z nodes (e.g., Z≥50). However, in an alternative embodiment, LSTM structure 610 could comprise two or more layers that each consists of Z nodes. Input data 605 are repeatedly fed through LSTM structure 610 until the nodes in LSTM structure 610 “forget” about the data. Machine-learning model 116 is defined such that data older than N time intervals are forgotten. LSTM structure 610 may utilize a sigmoidal activation function.

Densely connected structure 620 may comprise one or more, and generally a plurality of, layers of nodes. Each layer may have the same number Z of nodes (e.g., Z≥50) as LSTM structure 610. In the illustrated embodiment, densely connected structure 620 comprises four densely connected layers that each consists of Z nodes (e.g., 200 nodes if Z=50). The layer(s) of densely connected structure 620 may utilize a hyperbolic tangent activation function.

In an embodiment, each node in the last, and potentially only layer, of LSTM structure 610, is connected to each node in the initial layer of densely connected structure 620. In addition, each node in each layer of densely connected structure 620 may be connected to every node in each adjacent layer of densely connected structure 620. It should be understood that, even though all layers of LSTM structure 610 and densely connected structure 620 are fully connected in this manner, not all connections will necessarily be active during operation of machine-learning model 116.

In an embodiment, each layer of nodes in LSTM structure 610 and densely connected structure 620 have an identical number Z of nodes. The number Z of nodes in each layer of LSTM structure 610 and densely connected structure 620 may be selected to achieve sufficient accuracy within applicable computational constraints. In particular, increasing the number of nodes may increase the accuracy of machine-learning model 116, but will also increase the computational requirements (e.g., processing time, processing power, memory, power consumption, bandwidth, etc.) of machine-learning model 116. In a particular implementation, Z=50 was found to represent a suitable balance between these competing trade-offs.

All of the nodes in the final layer of densely connected structure 620 may be connected to aggregation node 630. Aggregation node combines all Z outputs of the Z nodes in the final layer of densely connected structure 620 into a single prediction 635. It should be understood that prediction 635 comprises a predicted value of each target parameter. As discussed elsewhere herein, the target parameter may comprise a storage parameter, such as water level, change in water level, water storage, change in water storage, storage capacity, or change in storage capacity of a water reservoir represented by input data 605.

### 8. Experimental Results

To test the performance of disclosed embodiments, a machine-learning model 116, comprising a recurrent neural network with long short-term memory, was trained and evaluated for seventeen water reservoirs in Texas, listed in the table below:

| USGS ID | Water Reservoir | Climate Division |
|---|---|---|
| 07227900 | Lake Meredith, Sanford, Texas | 1 |
| 07335600 | Lake Crook, Paris, Texas | 3 |
| 08022060 | Martin Lake, Tatum, Texas | 4 |
| 08045800 | Lake Weatherford, Weatherford, Texas | 3 |
| 08049800 | Joe Pool Lake, Duncanville, Texas | 3 |
| 08061550 | Lake Ray Hubbard, Forney, Texas | 3 |
| 08067600 | Lake Conroe, Conroe, Texas | 4 |
| 08080910 | White River Reservoir, Spur, Texas | 1 |
| 08082800 | Millers Creek Reservoir, Bomarton, Texas | 2, 3 |
| 08099000 | Leon Reservoir, Ranger, Texas | 3 |
| 08104650 | Lake Georgetown, Georgetown, Texas | 3 |
| 08110470 | Lake Limestone, Marquez, Texas | 3, 4 |
| 08118000 | Lake J. B. Thomas, Vincent, Texas | 2 |
| 08131200 | Twin Buttes Reservoir, San Angelo, Texas | 6 |
| 08164525 | Lake Texana, Edna, Texas | 8 |
| 08167700 | Canyon Lake, New Braunfels, Texas | 7 |
| 08210500 | Lake Corpus Christi, Mathis, Texas | 7, 9 |

The selected water reservoirs are located in sixteen different watersheds, as defined by their 8-digit USGS hydrological unit code. Joe Pool Lake and Lake Weatherford share a watershed. The selected water reservoirs also cover nine of the ten climate divisions in Texas, with some of the water reservoirs lying on the boundary between two climate divisions. The selected water reservoirs are spread across most of Texas and east of the Pecos River. These water reservoirs were selected based on the wide range of climate divisions, the availability of continuous data, and the length of the time period for which data were available. The geographic diversity of the area enables the resulting machine-learning model 116 to be robust against a bevy of potential weather inputs and operational use cases, including warmer and wetter conditions near the Gulf of Mexico and drier and colder conditions in the Texas panhandle.

The Texas Water Board provides elevation-capacity rating curves in a machine-readable format. This enabled rapid conversion from the gage heights of the water reservoirs to the storage capacities of the water reservoirs. Data from Jan. 1, 2020 through Dec. 31, 2020 were used for training in subprocess 320, and data from Jan. 1, 2021 through Dec. 31, 2022 were used for validation in subprocess 330.

In the tested implementation, LSTM structure 610 consisted of a single layer of fifty nodes, and densely connected structure 620 consisted of four layers of fifty nodes. All of the layers in LSTM structure 610 and densely connected structure 620 were fully connected. Feature vectors of fourteen tuples, representing fourteen consecutive days of temperature, precipitation, and water level, were used. Machine-learning model 116 was trained to predict the next day's change in water level, given such a feature vector. A learning rate of 10⁻⁴ was used for training.

Machine-learning model 116 was validated using a validation subset 318 spanning two years of data. Multi-day forecasts were generated by iterating machine-learning model 116 over the desired length of the forecast. Seven-day and fourteen-day forecasts were generated for every day in the two-year period, and then compared to observed water levels in the water reservoirs on the corresponding days. Feature vectors from validation subset 318 were also used to generate hindcasts out to sixteen days (i.e., Y=16), using process 500, which served as a proxy for the performance of machine-learning model 116 in an operational forecasting environment. Accuracy metrics, including mean absolute percent error (MAPE) and root mean squared error (RMSE), were computed for each water reservoir and hindcast time period. Performance of machine-learning model 116 was estimated after each training epoch using validation subset 318. The machine-learning model 116 with the smallest validation error was saved and considered to be the trained machine-learning model 116 for the experiment.

Generally, RMSE is not comparable across water reservoirs, since the water reservoirs vary in storage capacity and operating range. For example, Lake Ray Hubbard is one of the bigger water reservoirs used in the experiment, with a minimum storage of roughly 257,000 acre-feet and a storage capacity of roughly 452,000 acre-feet. Meanwhile, Lake Weatherford is one of the smallest water reservoirs with a minimum storage of roughly 9,300 acre-fee and a storage capacity of roughly 17,800 acre-feet. These differences in reservoir characteristics justify the use of MAPE to compare model performance, relative to the characteristics of the water reservoir. However, it is still useful to have absolute error statistics, such as RMSE, since these errors also represent changes in the reservoir height.

The table below depicts each accuracy metric for each tested water reservoir for both seven-day and fourteen-day forecasts:

| | 7-day Forecast | | 14-day Forecast | |
|---|---|---|---|---|
| | MAPE | RMSE | MAPE | RMSE |
| Water Reservoir | (%) | (acre-ft) | (%) | (acre-ft) |
| Lake Meredith | 0.32 | 786 | 0.54 | 1339 |
| Lake Crook | 1.52 | 214 | 2.07 | 261 |
| Martin Lake | 0.84 | 1146 | 1.40 | 1731 |
| Lake Weatherford | 0.95 | 203 | 2.04 | 353 |
| Joe Pool Lake | 1.01 | 3331 | 1.83 | 5883 |
| Lake Ray Hubbard | 0.81 | 4985 | 1.29 | 7186 |
| Lake Conroe | 0.75 | 5435 | 1.09 | 7073 |
| White River Reservoir | 1.85 | 263 | 3.14 | 377 |
| Millers Creek Reservoir | 0.82 | 305 | 1.49 | 458 |
| Leon Reservoir | 0.97 | 531 | 1.64 | 699 |
| Lake Georgetown | 1.55 | 535 | 3.16 | 955 |
| Lake Limestone | 1.36 | 3340 | 2.11 | 4961 |
| Lake J. B. Thomas | 2.10 | 3975 | 3.84 | 6380 |
| Twin Buttes Reservoir | 1.18 | 1572 | 2.33 | 2519 |
| Lake Texana | 1.37 | 3232 | 2.31 | 4797 |
| Canyon Lake | 0.42 | 2402 | 0.86 | 4020 |
| Lake Corpus Christi | 1.92 | 8720 | 3.17 | 13876 |

A successful machine-learning model 116 would be able to forecast seven days of storage capacities with no more than 5% error. The depicted performance demonstrates that machine-learning model 116 is capable of predicting reservoir storage capacity within this established benchmark. In particular, eight of the seventeen water reservoirs had MAPE below 1% for seven-day forecasting. In addition, eight of the seventeen water reservoirs had MAPE rates below 2% for fourteen-day forecasting. It can be seen that storage capacities of water reservoirs correlate well with time series of climatological and hydrological parameters for the watersheds of those water reservoirs. Given the high levels of predictive accuracy, machine-learning model 116 enables water resource managers to accurately predict the water levels of water reservoirs at least fourteen days into the future.

The above description of the disclosed embodiments is provided to enable any person skilled in the art to make or use the invention. Various modifications to these embodiments will be readily apparent to those skilled in the art, and the general principles described herein can be applied to other embodiments without departing from the spirit or scope of the invention. Thus, it is to be understood that the description and drawings presented herein represent a presently preferred embodiment of the invention and are therefore representative of the subject matter which is broadly contemplated by the present invention. It is further understood that the scope of the present invention fully encompasses other embodiments that may become obvious to those skilled in the art and that the scope of the present invention is accordingly not limited.

As used herein, the terms “comprising,” “comprise,” and “comprises” are open-ended. For instance, “A comprises B” means that A may include either: (i) only B; or (ii) B in combination with one or a plurality, and potentially any number, of other components. In contrast, the terms “consisting of,” “consist of,” and “consists of” are closed-ended. For instance, “A consists of B” means that A only includes B with no other component in the same context.

Combinations, described herein, such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or A and B and C, and any such combination may contain one or more members of its constituents A, B, and/or C. For example, a combination of A and B may comprise one A and multiple B's, multiple A's and one B, or multiple A's and multiple B's.

What is claimed is:

1. A method comprising using at least one hardware processor to, during a training phase:
acquire a training dataset comprising a plurality of labeled feature vectors, wherein each of the plurality of labeled feature vectors comprises a time series of a plurality of tuples, wherein each of the plurality of tuples comprises a value for each of one or more climate parameters and one or more reservoir parameters for a respective water reservoir, and wherein each of the plurality of labeled feature vectors is labeled with a target value of at least one storage parameter of the respective water reservoir; and
use the training dataset to train a machine-learning model to predict a value of the at least one storage parameter for any of a plurality of water reservoirs,
wherein the machine-learning model comprises a recurrent neural network with long short-term memory (LSTM).

2. The method of claim 1, wherein the recurrent neural network comprises an LSTM structure and a densely connected structure.

3. The method of claim 2, wherein the LSTM structure comprises at least one layer of nodes, and wherein the densely connected structure comprises a plurality of layers of nodes.

4. The method of claim 3, wherein each layer of nodes in the LSTM structure and the densely connected structure has an identical number of nodes.

5. The method of claim 4, wherein the number of nodes is at least fifty.

6. The method of claim 3, wherein each node in the at least one layer of the LSTM structure is connected to every node in an initial one of the plurality of layers of the densely connected structure.

7. The method of claim 3, wherein each node in each of the plurality of layers of the densely connected structure is connected to every node in each adjacent one of the plurality of layers of the densely connected structure.

8. The method of claim 3, wherein the recurrent neural network further comprises an aggregation node that outputs the predicted value of the at least one storage parameter, and wherein each node in a final one of the plurality of layers of the densely connected structure is connected to the aggregation node.

9. The method of claim 1, wherein the one or more climate parameters comprise temperature and precipitation.

10. The method of claim 9, wherein the one or more reservoir parameters comprise either a water level of the respective water reservoir, water storage in the respective water reservoir, or a storage capacity of the respective water reservoir.

11. The method of claim 1, wherein the at least one storage parameter comprises either a water level of the respective water reservoir, a change in water level of the respective water reservoir, water storage in the respective water reservoir, a change in water storage in the respective water reservoir, a storage capacity of the respective water reservoir, or a change in storage capacity of the respective water reservoir.

12. The method of claim 1, wherein each of the plurality of tuples in each time series represents one time interval within a plurality of consecutive time intervals.

13. The method of claim 12, wherein each of the plurality of consecutive time intervals is a twenty-four-hour period, and wherein the time series comprises at least fourteen tuples.

14. The method of claim 12, wherein the target value of the at least one storage parameter, with which each of the plurality of feature vectors is labeled, represents the at least one storage parameter at a subsequent time interval that is at least seven time intervals after a last one of the plurality of consecutive time intervals represented by the plurality of tuples in that feature vector.

15. The method of claim 1, wherein acquiring the training dataset comprises generating the training dataset, and wherein generating the training dataset comprises, for at least one water reservoir:
acquiring historical climate data that comprise observed values of the one or more climate parameters, spatially scattered in a non-uniform manner;
deriving a gridded dataset by interpolating a value of each of the one or more climate parameters for each of a plurality of points in a uniform grid based on the observed values of the one or more climate parameters in the historical climate data; and
calculating the value of each of the one or more climate parameters for the at least one respective water reservoir from the gridded dataset.

16. The method of claim 15, wherein the value of each of the one or more climate parameters for the at least one water reservoir are calculated by spatially aggregating a plurality of values of that climate parameter for at least a subset of the plurality of points representing a watershed of the at least one water reservoir.

17. The method of claim 1, wherein each of the plurality of tuples comprises a value of the at least one storage parameter, wherein the method further comprises using the at least one hardware processor to, during the training phase, validate the machine-learning model, and wherein validating the machine-learning model comprises, for each of one or more feature vectors in a validation subset of the training dataset, in each of a plurality of iterations:
input the feature vector to the machine-learning model to predict the value of the at least one storage parameter;
create a new tuple comprising the predicted value of the at least one storage parameter;
remove one of the plurality of tuples from a front of the feature vector; and
add the new tuple to an end of the feature vector.

18. The method of claim 1, further comprising using the at least one hardware processor to, during an operation phase:
receive an input feature vector comprising a time series of a plurality of tuples, wherein each of the plurality of tuples in the time series of the input feature vector comprises a value for each of the one or more climate parameters and the one or more reservoir parameters for a water reservoir of interest;
apply the trained machine-learning model to the input feature vector to predict the value of the at least one storage parameter for the water reservoir of interest in at least one future time interval; and
output the predicted value of the at least one storage parameter for the water reservoir of interest in the at least one future time interval to at least one downstream function.

19. A system comprising:
at least one hardware processor; and
one or more software modules that are configured to, when executed by the at least one hardware processor, during a training phase,
acquire a training dataset comprising a plurality of labeled feature vectors, wherein each of the plurality of labeled feature vectors comprises a time series of a plurality of tuples, wherein each of the plurality of tuples comprises a value for each of one or more climate parameters and one or more reservoir parameters for a respective water reservoir, and wherein each of the plurality of labeled feature vectors is labeled with a target value of at least one storage parameter of the respective water reservoir, and
use the training dataset to train a machine-learning model to predict a value of the at least one storage parameter for any of a plurality of water reservoirs,
wherein the machine-learning model comprises a recurrent neural network with long short-term memory (LSTM).

20. A non-transitory computer-readable medium having instructions stored therein, wherein the instructions, when executed by a processor, cause the processor to, during a training phase:
acquire a training dataset comprising a plurality of labeled feature vectors, wherein each of the plurality of labeled feature vectors comprises a time series of a plurality of tuples, wherein each of the plurality of tuples comprises a value for each of one or more climate parameters and one or more reservoir parameters for a respective water reservoir, and wherein each of the plurality of labeled feature vectors is labeled with a target value of at least one storage parameter of the respective water reservoir; and
use the training dataset to train a machine-learning model to predict a value of the at least one storage parameter for any of a plurality of water reservoirs,
wherein the machine-learning model comprises a recurrent neural network with long short-term memory (LSTM).
